(19) United States
(12) Patent Application Publication
(10) Pub. No.: US 2026/0164717 A1
(43) Pub. Date: Jun. 11, 2026

(54) SEMICONDUCTOR DEVICE STRUCTURE AND METHODS OF FORMING THE SAME

(71) Applicant: TAIWAN SEMICONDUCTOR MANUFACTURING COMPANY, LTD., Hsinchu (TW)

(72) Inventors: Ting-Hsiang CHANG, New Taipei (TW); Shu Ling LIAO, Taichung (TW); Sung-En LIN, Hsinchu (TW); Tze-Liang LEE, Hsinchu (TW)

(21) Appl. No.: 18/969,377

(22) Filed: Dec. 5, 2024

(51) Int. Cl. H10D 30/67; H01L 21/02; H10D 30/01; H10D 30/43; H10D 62/10; H10D 62/13; H10D 64/01; H10D 84/01; H10D 84/83

(52) U.S. Cl. CPC H10D 30/6735; H10D 30/014; H10D 30/43; H10D 30/6757; H10D 62/121; H10D 62/151; H10D 64/017; H10D 64/021; H10D 84/013; H10D 84/83; H10P 14/6336

(57) ABSTRACT

A semiconductor device structure, along with methods of forming such, are described. The structure includes a first semiconductor layer disposed adjacent a substrate portion and a second semiconductor layer disposed on the first semiconductor layer. The first and second semiconductor layers are distinct from each other. The structure further includes a dielectric layer disposed on the second semiconductor layer, a source/drain region disposed on the dielectric layer, an interlayer dielectric layer disposed over the source/drain region, and a first conductive feature disposed through the interlayer dielectric layer. The first conductive feature is electrically connected to the source/drain region.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

Therefore, there is a need to improve processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1, 2, 3, 4, 5, and 6 are perspective views of various stages of manufacturing a semiconductor device structure, in accordance with some embodiments.

FIGS. 7A, 7B, 7C, 7D, 7E, 7F, 7G, and 7H are partial cross-sectional side views of various stages of manufacturing the semiconductor device structure taken along line A-A of

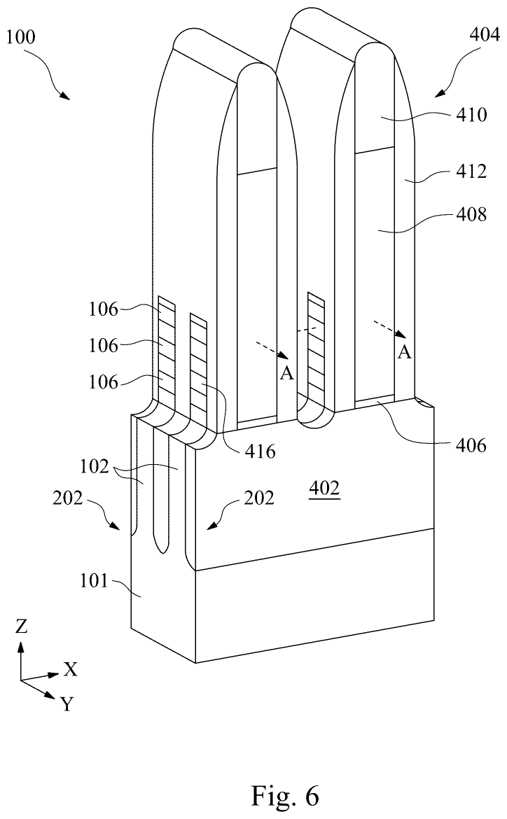

FIG. 6, in accordance with some embodiments.

FIG. 8 is a perspective view of one of various stages of manufacturing the semiconductor device structure, in accordance with some embodiments.

FIGS. 9, 10, 11 are cross-sectional side views of various stages of manufacturing the semiconductor device structure taken along line B-B of FIG. 8, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

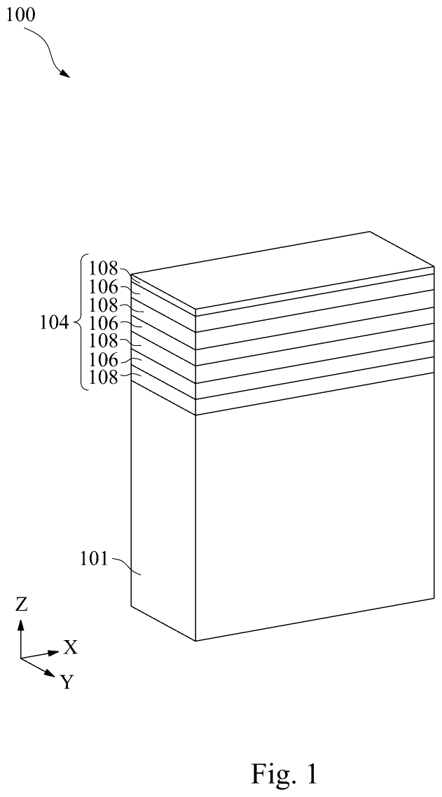

FIGS. 1-11 show sequential processes for manufacturing a semiconductor device structure 100, in accordance with some embodiments. It is understood that additional operations can be provided before, during, and after processes shown by FIGS. 1-11 and some of the operations described below can be replaced or eliminated, for additional embodiments of the method. The order of the operations/processes may be interchangeable.

FIGS. 1-6 are perspective views of various stages of manufacturing a semiconductor device structure, in accordance with some embodiments. As shown in FIG. 1, a stack of semiconductor layers 104 is formed over a substrate 101. The substrate 101 may be a semiconductor substrate. In some embodiments, the substrate 101 includes a crystalline semiconductor layer on at least the surface of the substrate 101. The substrate 101 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). In this embodiment, the substrate 101 is made of Si. In some embodiments, the substrate 101 is a silicon-on-insulator (SOI) substrate, which includes an insulating layer (not shown) disposed between two silicon layers. In one aspect, the insulating layer is an oxide.

The substrate 101 may include one or more buffer layers (not shown) on the surface of the substrate 101. The buffer layers can serve to gradually change the lattice constant from that of the substrate to that of the source/drain (S/D) regions to be grown on the substrate 101. The buffer layers may be formed from epitaxially grown single crystalline semiconductor materials such as, but not limited to Si, Ge, germanium tin (GeSn), SiGe, GaAs, InSb, GaP, GaSb, InAlAs, InGaAs, GaSbP, GaAsSb, GaN, and InP. In one embodiment, the substrate 101 includes SiGe buffer layers epitaxially grown on the silicon substrate 101. The germanium concentration of the SiGe buffer layers may increase from 30 atomic percent germanium for the bottom-most buffer layer to 70 atomic percent germanium for the top-most buffer layer.

The substrate 101 may include various regions that have been suitably doped with impurities (e.g., p-type or n-type impurities). The dopants are, for example boron for a p-type field effect transistor (FET) and phosphorus for an n-type FET.

The stack of semiconductor layers 104 includes first semiconductor layers 106 and second semiconductor layers 108. The first semiconductor layers 106 and the second semiconductor layers 108 are made of semiconductor materials having different etch selectivity and/or oxidation rates. For example, the first semiconductor layers 106 are made of Si and the second semiconductor layers 108 are made of SiGe. In one aspect, the first semiconductor layers 106 are made of undoped Si. The second semiconductor layers 108 may be doped to enhance etching selectivity against the first semiconductor layers 106. In some embodiments, the stack of semiconductor layers 104 includes alternating first and second semiconductor layers 106, 108, as shown in FIG. 1. The first semiconductor layers 106 or portions thereof may form nanostructure channel(s) of the semiconductor device structure 100 at a later stage. The semiconductor device structure 100 may include a nanostructure transistor. The term nanostructure is used herein to designate any material portion with nanoscale, or even microscale dimensions, and having any suitable shape, such as an elongate shape, regardless of the cross-sectional shape of this portion. Thus, this term designates both circular and substantially circular cross-section elongate material portions, and beam or bar-shaped material portions including for example a cylindrical in shape or substantially rectangular cross-section. The nanostructure channel(s) of the semiconductor device structure 100 may be surrounded by the gate electrode layer. The nanostructure transistors may be referred to as nanosheet transistors, nanowire transistors, gate-all-around (GAA) transistors, multi-bridge channel (MBC) transistors, or any transistors having the gate electrode layer surrounding the channels. The use of the first semiconductor layers 106 to define a channel or channels of the semiconductor device structure 100 is further discussed below.

It is noted that 3 layers of the first semiconductor layers 106 and 4 layers of the second semiconductor layers 108 are alternately arranged as illustrated in FIG. 1, which is for illustrative purposes and not intended to be limiting beyond what is specifically recited in the claims. It can be appreciated that any number of first and second semiconductor layers 106, 108 can be formed in the stack of semiconductor layers 104; the number of layers depending on the predetermined number of channels for the semiconductor device structure 100. In some embodiments, the number of first semiconductor layers 106, which is the number of channels, is between 3 and 8. In some embodiments, the topmost second semiconductor layer 108 is not present.

As described in more detail below, the first semiconductor layers 106 may serve as channels for the semiconductor device structure 100 and the thickness is chosen based on device performance considerations. In some embodiments, each first semiconductor layer 106 has a thickness ranging from about 6 nanometers (nm) to about 12 nm. The second semiconductor layers 108 may eventually be removed and serve to define a vertical distance between adjacent channels for the semiconductor device structure 100 and the thickness is chosen based on device performance considerations. In some embodiments, each second semiconductor layer 108 has a thickness ranging from about 2 nm to about 10 nm.

The first and second semiconductor layers 106, 108 are formed by any suitable deposition process, such as epitaxy. By way of example, epitaxial growth of the layers of the stack of semiconductor layers 104 may be performed by a molecular beam epitaxy (MBE) process, a metalorganic chemical vapor deposition (MOCVD) process, and/or other suitable epitaxial growth processes.

A mask structure (not shown) may be formed over the stack of semiconductor layers 104. The mask structure may include an oxygen-containing layer and a nitrogen-containing layer. The oxygen-containing layer may be a pad oxide layer, such as a SiO₂ layer. The nitrogen-containing layer may be a pad nitride layer, such as Si₃N₄. The mask structure may be formed by any suitable deposition process, such as chemical vapor deposition (CVD) process.

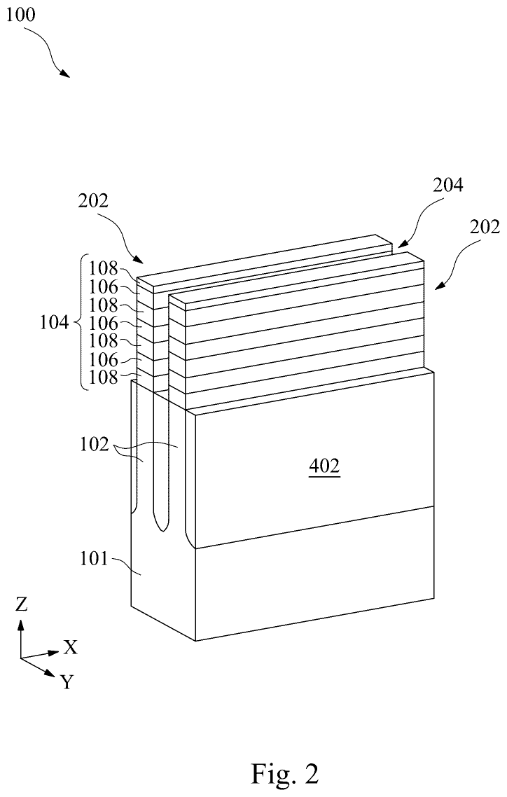

FIG. 2 is a perspective view of one of the various stages of manufacturing the semiconductor device structure 100, in accordance with some embodiments. As shown in FIG. 2, fins 202 are formed. In some embodiments, each fin 202 includes a substrate portion 102 formed from the substrate 101, a portion of the stack of semiconductor layers 104, and a portion of the mask structure 110. The fins 202 may be fabricated using suitable processes including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the fins 202 by etching the stack of semiconductor layers 104 and the substrate 101. The etch process can include dry etch, wet etch, reactive ion etch (RIE), and/or other suitable processes. As shown in FIG. 2, two fins 202 are formed, but the number of the fins 202 is not limited to two.

In some embodiments, the fins 202 may be fabricated using suitable processes including photolithography and etch processes. The photolithography process may include forming a photoresist layer (not shown) over the mask structure (not shown), exposing the resist to a pattern, performing post-exposure bake processes, and developing the resist to form a patterned resist. In some embodiments, patterning the resist to form the patterned resist may be performed using an electron beam (e-beam) lithography process. The patterned resist may then be used to protect regions of the substrate 101, and layers formed thereupon, while an etch process forms trenches 204 in unprotected regions through the mask structure 110, the stack of semiconductor layers 104, and into the substrate 101, thereby leaving the extending fins 202. The trenches 204 may be etched using a dry etch (e.g., RIE), a wet etch, and/or combination thereof.

In some embodiments, a second semiconductor layer 108 is located at the top of each fin 202, as shown in FIG. 2. In some embodiments, a first semiconductor layer 106 is located at the top of each fin 202.

As shown in FIG. 2, an insulating material 402 is formed on the substrate 101. The insulating material 402 may be first formed over the substrate 101 so that the fins 202 are embedded in the insulating material 402. Then, a planarization operation, such as a chemical mechanical polishing (CMP) process and/or an etch-back process, is performed such that the tops of the fins 202 are exposed from the insulating material 402. Then, the insulating material 402 may be recessed by removing a portion of the insulating material 402 located between adjacent fins 202. The recessing of the insulating material 402 may be formed by any suitable process, such as dry etch or wet etch that selectively removes the insulating material 402 but not the semiconductor materials of the first and second semiconductor layers 106, 108. The recessed insulating material 402 may be the shallow trench isolation (STI). The insulating material 402 includes a top surface that may be level with or below a surface of the second semiconductor layer 108 in contact with the substrate portion 102 of the substrate 101.

The insulating material 402 may be made of an oxygen-containing material, such as silicon oxide or fluorine-doped silicate glass (FSG); a nitrogen-containing material, such as silicon nitride, silicon oxynitride (SiON), SiOCN, SiCN; a low-K dielectric material; or any suitable dielectric material. The insulating material 402 may be formed by any suitable method, such as low-pressure chemical vapor deposition (LPCVD), plasma enhanced CVD (PECVD) or flowable CVD (FCVD).

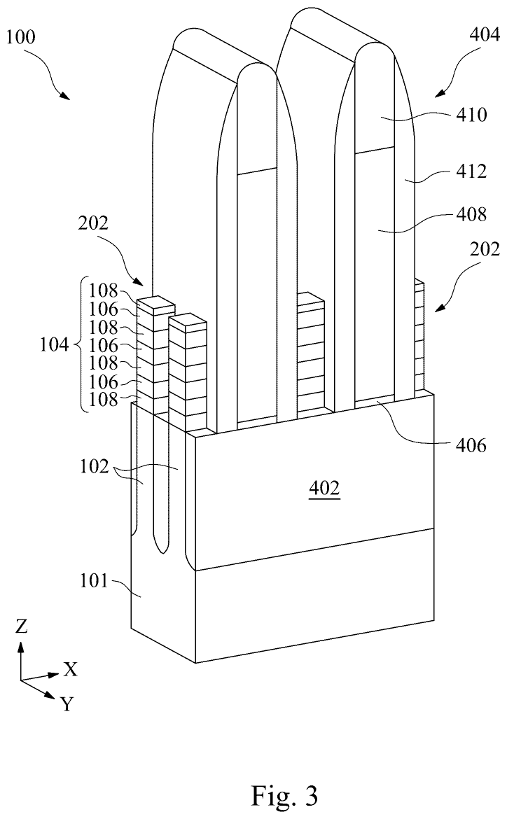

As shown in FIG. 3, one or more sacrificial gate stacks 404 are formed on the semiconductor device structure 100. The sacrificial gate stack 404 may include a sacrificial gate dielectric layer 406, a sacrificial gate electrode layer 408, and a mask structure 410. The sacrificial gate dielectric layer 406 may include one or more layers of dielectric material, such as SiO₂, SiN, a high-K dielectric material, and/or other suitable dielectric material. In some embodiments, the sacrificial gate dielectric layer 406 may be deposited by a CVD process, a sub-atmospheric CVD (SACVD) process, a FCVD process, an ALD process, a PVD process, or other suitable process. The sacrificial gate electrode layer 408 may include polycrystalline silicon (polysilicon). The mask structure 410 may include an oxygen-containing layer and a nitrogen-containing layer.

The sacrificial gate stacks 404 may be formed by first depositing blanket layers of the sacrificial gate dielectric layer 406, the sacrificial gate electrode layer 408, and the mask structure 410, followed by pattern and etch processes. The blanket layers of the sacrificial gate dielectric layer 406, the sacrificial gate electrode layer 408, and the mask structure 410 may be formed by various processes such as CVD (including both LPCVD and PECVD), PVD, ALD, thermal oxidation, e-beam evaporation, or other suitable deposition techniques, or combinations thereof. The pattern process includes a lithography process (e.g., photolithography or e-beam lithography) which may further include photoresist coating (e.g., spin-on coating), soft baking, mask aligning, exposure, post-exposure baking, photoresist developing, rinsing, drying (e.g., spin-drying and/or hard baking), other suitable lithography techniques, and/or combinations thereof. In some embodiments, the etch process may include dry etch (e.g., RIE), wet etch, other etch methods, and/or combinations thereof. By patterning the sacrificial gate stack 404, the stacks of semiconductor layers 104 of the fins 202 are partially exposed on opposite sides of the sacrificial gate stack 404. As shown in FIG. 3, two sacrificial gate stacks 404 are formed, but the number of the sacrificial gate stacks 404 is not limited to two. More than two sacrificial gate stacks 404 are arranged along the X direction in some embodiments.

As shown in FIG. 3, a spacer 412 is formed on the sidewalls of the sacrificial gate stacks 404. The spacer 412 may be formed by depositing a conformal layer that is subsequently etched back to form sidewall spacers 412. For example, a spacer material layer can be disposed conformally on the exposed surfaces of the semiconductor device structure 100. The conformal spacer material layer may be formed by an ALD process. Subsequently, anisotropic etch is performed on the spacer material layer using, for example, RIE. During the anisotropic etch process, most of the spacer material layer is removed from horizontal surfaces, such as the tops of the fins 202 and the tops of the sacrificial gate stacks 404, leaving the spacers 412 on the vertical surfaces, such as the sidewalls of sacrificial gate stack 404. The spacer 412 may be made of a dielectric material such as silicon oxide, silicon nitride, silicon carbide, silicon oxynitride, SiCN, silicon oxycarbide, SiOCN, and/or combinations thereof. In some embodiments, the spacer 412 includes multiple layers, such as main spacer walls, liner layers, and the like.

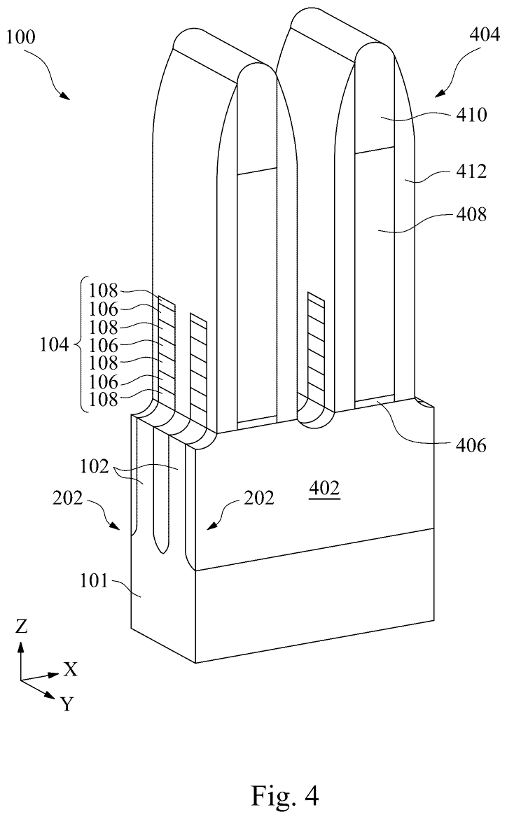

Next, exposed portions of the fins 202 not covered by the sacrificial gate stacks 404 and the spacers 412 are recessed, as shown in FIG. 4. The recess of the exposed portions of the fins 202 may be performed by an etch process, such as dry etch, wet etch, or a combination thereof. In some embodiments, exposed portions of the stacks of semiconductor layers 104 of the fins 202 are removed, exposing portions of the substrate portions 102. In some embodiments, a portion of the substrate portions 102 may be also removed. As shown in FIG. 4, the exposed portions of the fins 202 are recessed to a level below the top surface of the insulating material 402.

At this stage, end portions of the stacks of semiconductor layers 104 under the sacrificial gate stacks 404 and the spacers 412 have substantially flat surfaces which may be flush with corresponding spacers 412. In some embodiments, the end portions of the stacks of semiconductor layers 104 under the sacrificial gate stacks 404 and spacers 412 are slightly horizontally etched.

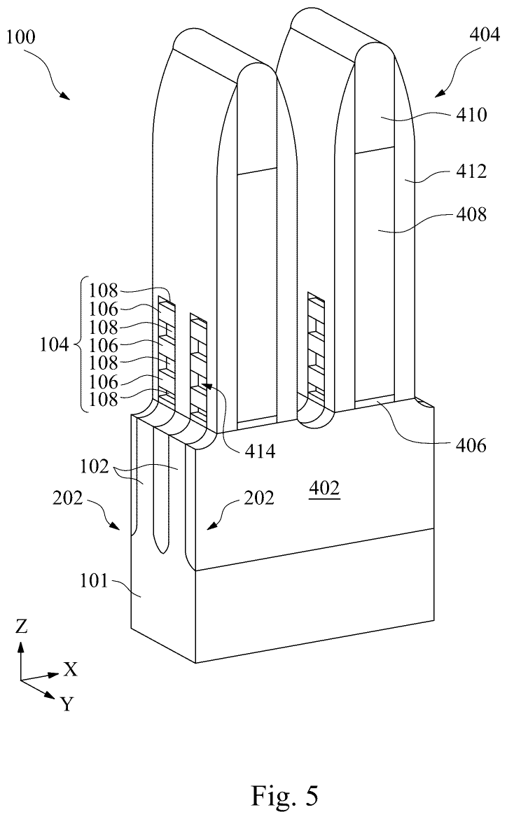

As shown in FIG. 5, the edge portions of each second semiconductor layer 108 are removed, forming gaps 414. In some embodiments, the portions of the second semiconductor layers 108 are removed by a selective wet etch process that does not remove the first semiconductor layers 106. For example, in cases where the second semiconductor layers 108 are made of SiGe, and the first semiconductor layers 106 are made of silicon, a selective wet etch including an ammonia and hydrogen peroxide mixtures (APM) may be used.

As shown in FIG. 6, dielectric spacers 416 are formed in the gaps 414. In some embodiments, the dielectric spacers 416 may be made of SiON, SiCN, SiOC, SiOCN, or SiN. In some embodiments, the dielectric spacers 416 may be formed by first forming a conformal dielectric layer using a conformal deposition process, such as ALD, followed by an anisotropic etch to remove portions of the conformal dielectric layer other than the dielectric spacers 416. The dielectric spacers 416 may be protected by the first semiconductor layers 106 and the spacers 412 during the anisotropic etch process. In some embodiments, the dielectric spacers 416 may be flush with the spacers 412.

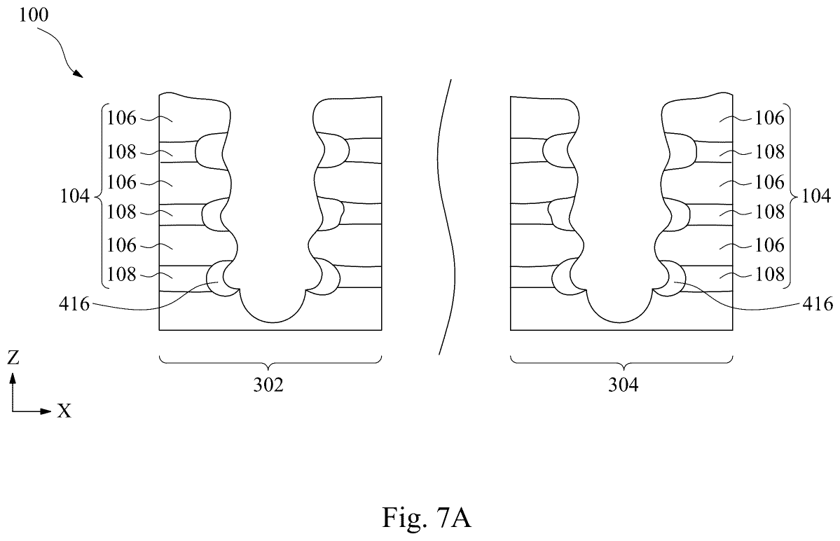

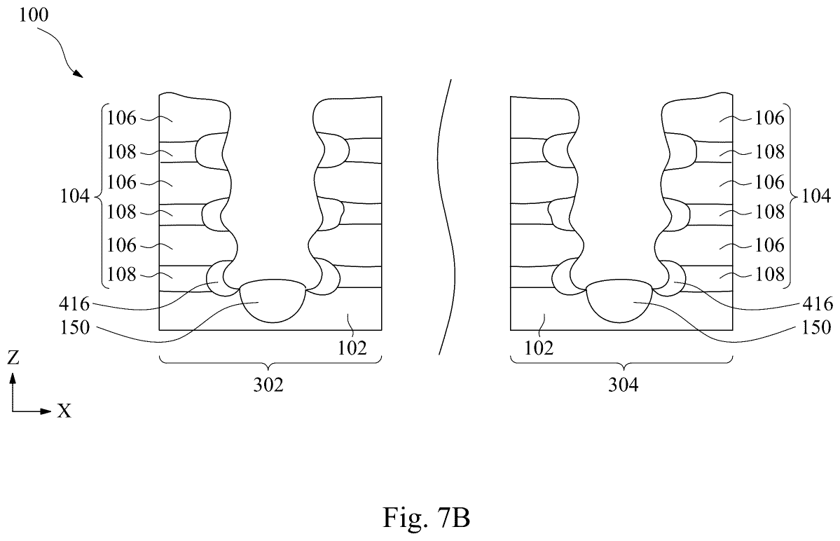

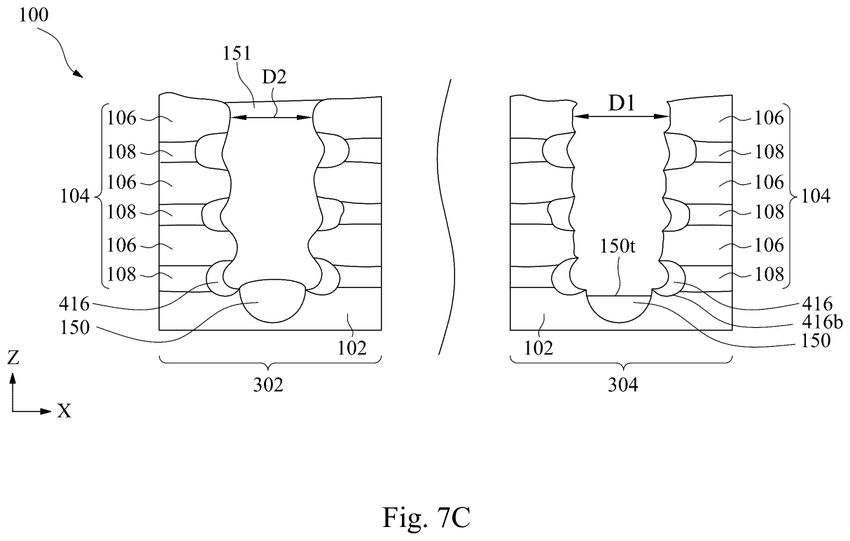

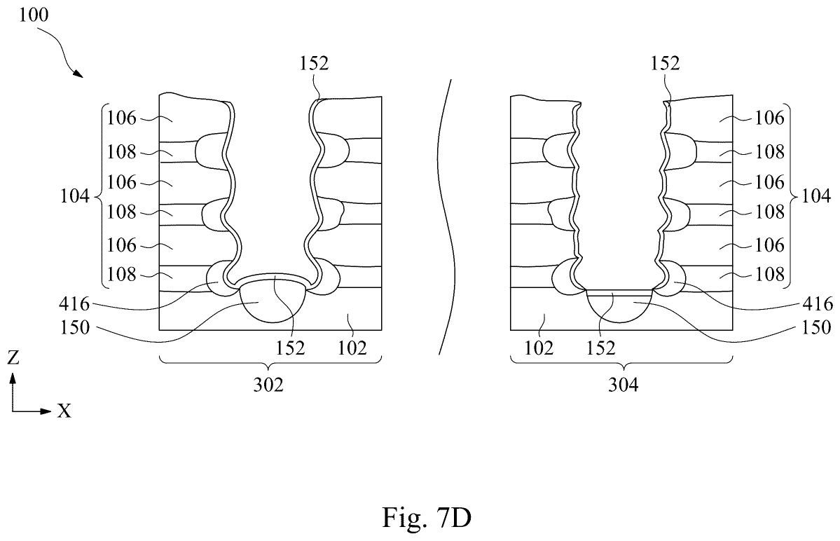

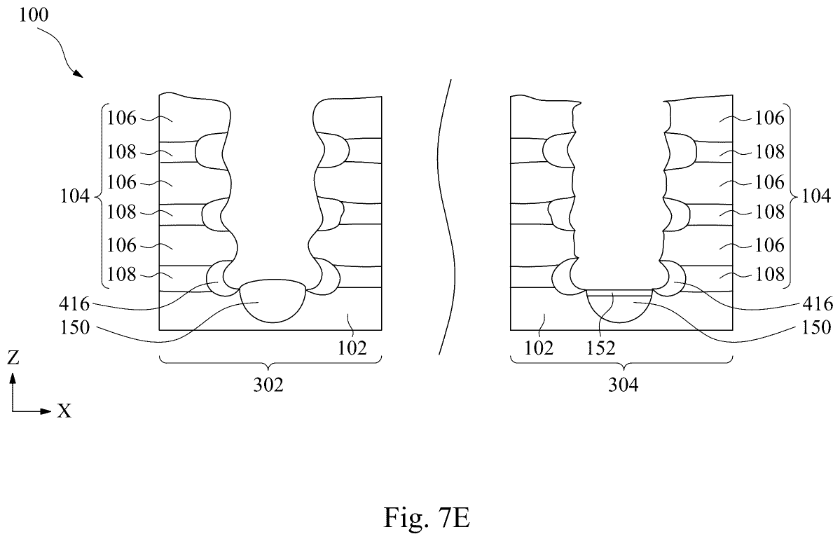

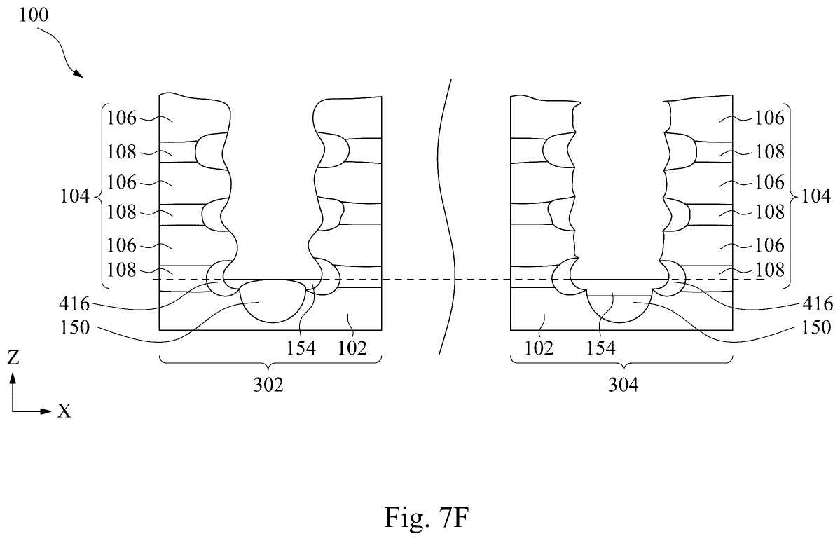

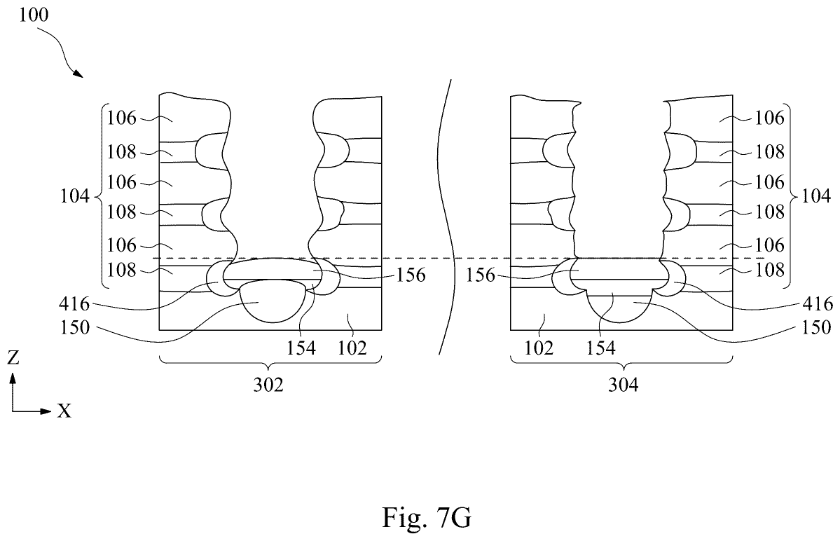

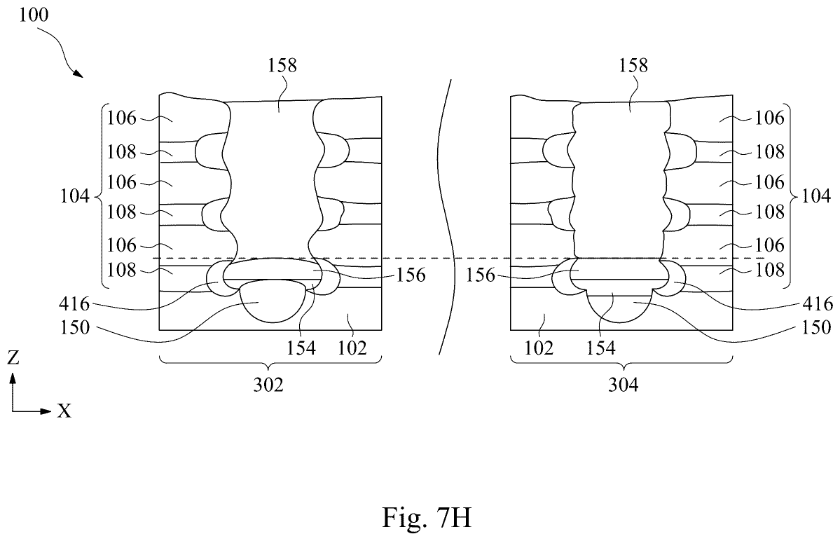

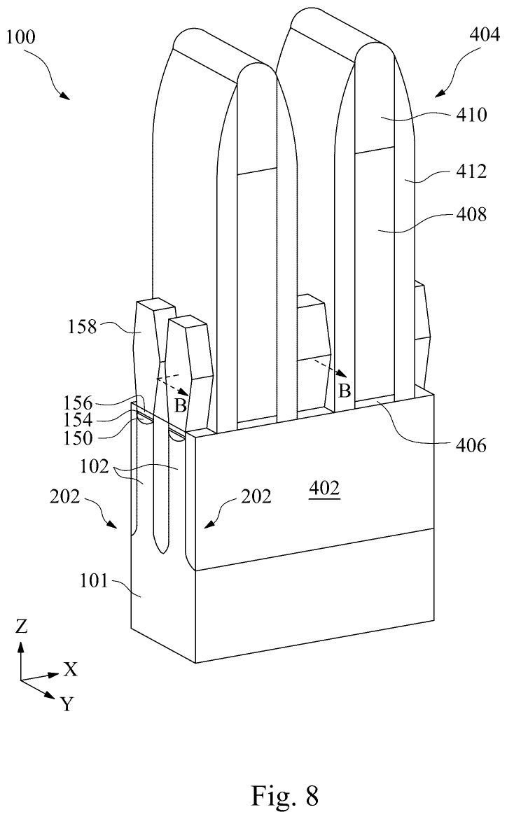

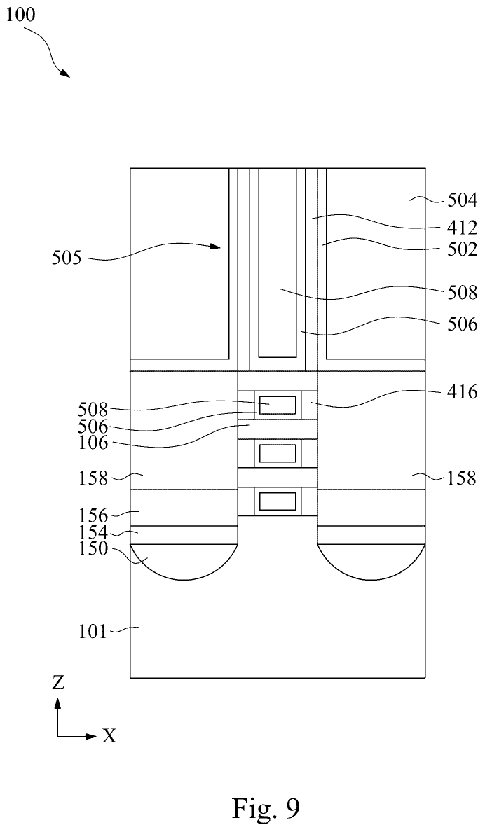

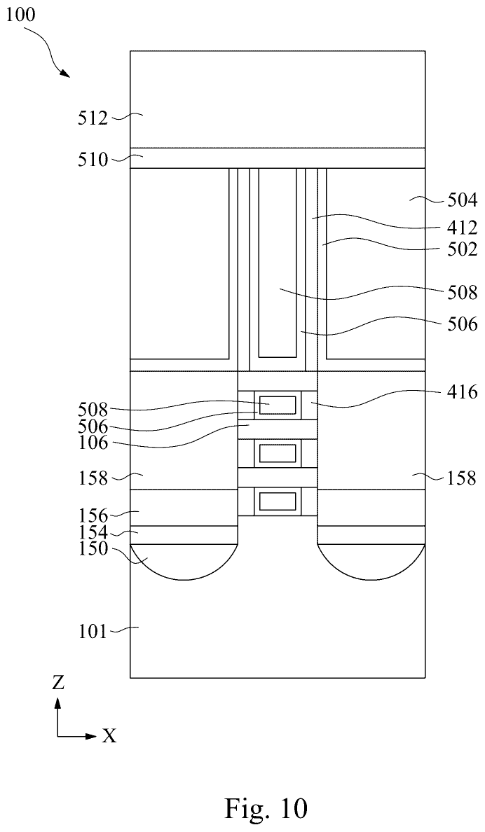

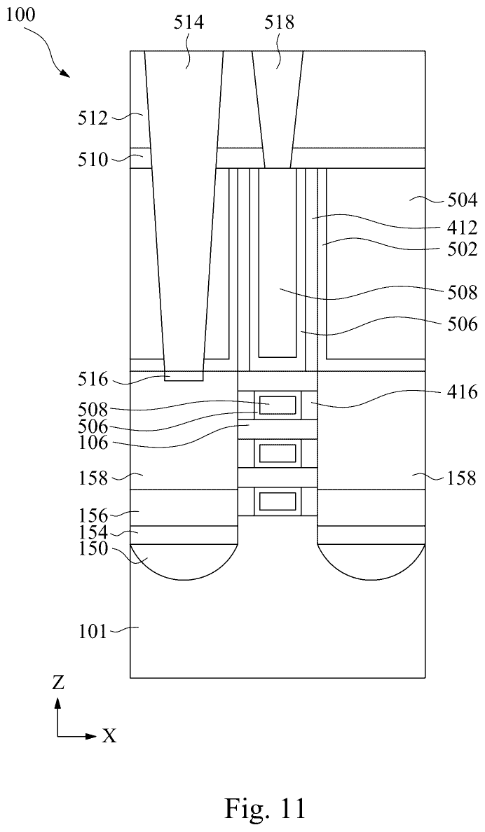

FIGS. 7A to 7H are partial cross-sectional side views of various stages of manufacturing the semiconductor device structure 100 taken along line A-A of FIG. 6, in accordance with some embodiments. The sacrificial gate stacks 404 and the spacers 412 are omitted in FIGS. 7A to 7I for clarity. In some embodiments, regions of the semiconductor device structure 100 in which n-type devices or p-type devices are formed are respectively referred to herein as “NMOS regions” or “PMOS regions.” As shown in FIG. 7A, the semiconductor device structure 100 includes an NMOS region 302 and a PMOS region 304, which is at the manufacturing stage shown in FIG. 6.

Next, as shown in FIG. 7B, a semiconductor layer 150 is formed on the exposed substrate portions 102 in the NMOS region 302 and the PMOS region 304. The semiconductor layer 150 may be formed adjacent the substrate portion 102 located under the bottommost second semiconductor layer 108, as shown in FIG. 7B. In some embodiments, the semiconductor layer 150 includes undoped silicon or undoped SiGe. The semiconductor layer 150 may be first formed on semiconductor surfaces, such as on the exposed substrate portions 102 and on the semiconductor layers 106, by epitaxy. In some embodiments, the semiconductor layer 150 is crystalline silicon or crystalline SiGe. A subsequent etch process is performed to remove the portions of the semiconductor layer 150 formed on the first semiconductor layers 106. In some embodiments, the semiconductor layer 150 formed on the exposed substrate portions 102 may form a convex top surface in both NMOS region 302 and the PMOS region 304. In some embodiments, the semiconductor layer 150 has a thickness ranging from about 5 nm to about 50 nm along the Z direction.

As shown in FIG. 7C, a mask layer 151 is formed in the opening between adjacent stacks of semiconductor layers 104 along the X direction in the NMOS region 302, and the opening between adjacent stacks of semiconductor layers 104 along the X direction in the PMOS region 304 is enlarged. The mask layer 151 may include any suitable material. In some embodiments, the mask layer 151 is a bottom anti-reflective coating (BARC) layer. The mask layer 151 may fill the space between adjacent stacks of semiconductor layers 104 in the NMOS region 302 and may be formed over the sacrificial gate stacks 404 (FIG. 6) and the spacers 412 (FIG. 6) in the NMOS region 302. Then, an etch process is performed to enlarge the opening between the adjacent stacks of semiconductor layers 104 along the X direction in the PMOS region 304. The etch process may be an isotropic etch process. In some embodiments, the etch process is a wet etch process. In some embodiments, the etch process utilizes an etchant that etches semiconductor materials at a faster rate than dielectric materials. For example, the etchant may remove portions of the first semiconductor layers 106 and the semiconductor layer 150, while the dielectric spacers 416 are substantially unaffected by the etchant. The etch process does not substantially affect the mask layer 151 formed in the NMOS region 302. As a result, in some embodiments, the distance D1 between adjacent first semiconductor layers 106 along the X direction in the PMOS region 304 is greater than the distance D2 between adjacent first semiconductor layers 106 along the X direction in the NMOS region 302, as shown in FIG. 7C. In some embodiments, a ratio of the distance D1 to the distance D2 ranges from about 1.05:1 to about 1.2:1. In some embodiments, a source/drain region 158 (FIG. 7H) formed in the NMOS region 302 has a higher electrical conductivity than a source/drain region 158 (FIG. 7H) formed in the PMOS region 304. The enlarged opening between adjacent stacks of semiconductor layers 104 in the PMOS region 304 leads to enlarged source/drain region 158 in the PMOS region 304. As a result, the electrical conductivity of the source/drain region 158 in the PMOS region 304 is increased to match the electrical conductivity of the source/drain region 158 in the NMOS region 302.

In some embodiments, as shown in FIG. 7C, the etch process to enlarge the opening between adjacent stacks of semiconductor layers 104 removes a portion of the semiconductor layer 150. In some embodiments, the thickness of the semiconductor layer 150 is reduced by 2 nm to about 5 nm along the Z direction. As a result, a top surface 150t of the semiconductor layer 150 may be located at a level below the bottom surface 416b of the dielectric spacer 416 in the PMOS region 304, as shown in FIG. 7C. Furthermore, the top surface 150t of the semiconductor layer 150 in the PMOS region 304 may be substantially flat or may have a concave profile due to the etch process, compared to the convex top surface of the semiconductor layer 150 in the NMOS region 302, as shown in FIG. 7C.

In some embodiments, the etch process laterally etches the first semiconductor layers 106 in the PMOS region 304, and the end portion of the first semiconductor layer 106 in the PMOS region 304 has a concave profile, as shown in FIG. 7C. The first semiconductor layers 106 in the NMOS region 302 are not exposed to the etch process. Thus, the end portion of the first semiconductor layer 106 in the NMOS region 302 has a convex profile, as shown in FIG. 7C.

FIGS. 7D, 7E, and 7F illustrate a process to form a semiconductor layer 154 (FIG. 7F) on the semiconductor layer 150 in the PMOS region 304. The semiconductor layer 154 may be formed using a multi-cycle of depositing and etching process, which may be referred to as a multi-cycle dep-etch process. In some embodiments, as shown in FIG. 7D, a semiconductor layer 152 is deposited on the exposed surface of the semiconductor device structure 100. The semiconductor layer 152 may be an amorphous semiconductor layer, such as an amorphous silicon layer. The amorphous semiconductor layer may be easier to process compared to crystalline semiconductor layer during the subsequent processes, such as the processes described in FIGS. 7E and 7F. In some embodiments, the amorphous silicon layer is undoped. The semiconductor layer 152 may be deposited by any suitable process. In some embodiments, the semiconductor layer 152 is deposited by PECVD. For example, a silicon-containing precursor, such as SiH₄, may be introduced into a processing chamber, and a silicon-containing plasma is formed in the processing chamber. The plasma may be formed by any suitable method. In some embodiment the plasma is a capacitively coupled plasma (CCP), an inductively coupled plasma (ICP), a microwave coupled plasma, or a remote plasma. The PECVD may have a first plasma frequency, such as less than about 30 MHz. In some embodiments, other gases, such as hydrogen gas (H₂), may be co-flowed with the precursor into the processing chamber to enhance the properties of the semiconductor layer 152. In some embodiments, the semiconductor layer 152 is a hydrogenated amorphous silicon layer. Compared to the un-hydrogenated amorphous silicon layer, the dangling bonds defects in the hydrogenated amorphous silicon layer is substantially less than in the un-hydrogenated amorphous silicon layer.

Next, as shown in FIG. 7E, an etch process is performed to remove the semiconductor layer 152 formed in the NMOS region 302 and to remove portions of the semiconductor layer 152 formed in the PMOS region 304. In some embodiments, the etch process is an in-situ etch process. For example, after the deposition of the semiconductor layer 152, the processing chamber is purged, and then an etchant is introduced into the processing chamber to remove the semiconductor layer 152 formed in the NMOS region 302 and to remove portions of the semiconductor layer 152 formed in the PMOS region 304. In some embodiments, the etchant is H₂. In some embodiments, a carrier gas, such as He or Ar, may be also flowed along with the H₂. The etch process may be a plasma etch process. In some embodiments, the plasma etch process utilizes a CCP and has a second plasma frequency substantially greater than the first plasma frequency. In some embodiments, the second plasma frequency is greater than about 30 MHz, such as from about 30 MHz to about 50 MHz, for example 40 MHz. At the higher plasma frequency, the ion angle is wider, which lowers hydrogen ion energy, and there are more hydrogen radicals. More hydrogen radicals and less hydrogen ions tends to perform a more isotropic etch process. As a result, the portions of the first semiconductor layer 152 formed on the sidewalls in the NMOS region 302 and the PMOS region 304 are removed.

Furthermore, in some embodiments, the etch process utilizes pulsed plasma power to further limit the hydrogen ions from reaching the bottoms of the openings between the adjacent stacks of semiconductor layers 104 in the NMOS region 302 and the PMOS region 304. The pulsed plasma power of the etch process reduces the energy of the hydrogen ions, leading to less hydrogen ions reaching the bottoms of the openings between the adjacent stacks of semiconductor layers 104 in the NMOS region 302 and the PMOS region 304. In some embodiments, the pulsed plasma power has a pulsing duty cycle of about 20 percent to about 80 percent, such as about 50 percent. In some embodiments, the opening between the adjacent stacks of semiconductor layers 104 in the NMOS region 302 has a first aspect ratio less than a second aspect ratio of the opening between the adjacent stacks of semiconductor layers 104 in the PMOS region 304, due to the reduced thickness of the semiconductor material 150 in the PMOS region 304. In some embodiments, the first aspect ratio is about 5.9 to about 6.1, and the second aspect ratio is about 6.2 to about 6.5. In other words, the portion of the semiconductor layer 152 located at the bottom of the opening between the adjacent stacks of semiconductor layers 104 in the PMOS region 304 is located at a level below the portion of the semiconductor layer 152 located at the bottom of the opening between the adjacent stacks of semiconductor layers 104 in the NMOS region 302 along the Z direction. Thus, in some embodiments, the portions of the semiconductor layer 152 located at the bottoms of the openings between the adjacent stacks of semiconductor layers 104 in the NMOS region 302 and the PMOS region 304 are etched back through hydrogen radical gradient. As a result, the portion of the semiconductor layer 152 located at the bottom of the opening between the adjacent stacks of semiconductor layers 104 in the NMOS region 302 is substantially removed, while most of the semiconductor layer 152 located at the bottom of the opening between the adjacent stacks of semiconductor layers 104 in the PMOS region 304 remains. This is due to the portion of the semiconductor layer 152 located at the bottom of the opening between the adjacent stacks of semiconductor layers 104 in the NMOS region 302 being located at a level along the Z direction substantially higher than the portion of the semiconductor layer 152 located at the bottom of the opening between the adjacent stacks of semiconductor layers 104 in the PMOS region 304.

In some embodiments, instead of a plasma etch process utilizing higher plasma frequency and pulsed plasma power to reduce the number of hydrogen ions, other plasma etch process may be performed. For example, a plasma etch process utilizing remote plasma may be performed to etch back the semiconductor layer 154. The remote plasma produces substantially more hydrogen radicals than hydrogen ions. In such embodiment, the plasma frequency of the plasma etch process utilizing remote plasma may be the same as the plasma frequency of the PECVD process. Furthermore, the plasma power may not be pulsed. In some embodiments, a plasma etch process utilizing ICP with an ion filter is performed. The ion filter blocks the hydrogen ions from contacting the semiconductor device structure 100. Similarly, the plasma frequency of the plasma etch process utilizing ICP with the ion filter may be the same as the plasma frequency of the PECVD process, and the plasma power may not be pulsed.

The deposition process and the etch process described in FIGS. 7D and 7E, respectively, may be one cycle of the multi-cycle dep-etch process to form the semiconductor layer 154 (FIG. 7F). In some embodiments, the deposition rate of the semiconductor layer 152 in the NMOS region 302 is about 0.2 angstroms per cycle, while the deposition rate of the semiconductor layer 152 in the PMOS region 304 is about 1.5 angstroms per cycle.

Next, as shown in FIG. 7F, the cycle is repeated multiple times to form the semiconductor layer 154 in the NMOS region 302 and the PMOS region 304. The semiconductor layer 154 is the result of the formation of a plurality of semiconductor layers 152. In some embodiments, about 20 cycles of dep-etch process are performed, the thickness of the semiconductor layer 154 in the PMOS region 304 is about 3 nm, and the thickness of the semiconductor layer 154 in the NMOS region 302 is about 0.4 nm. As described above, in some embodiments, the top surface of the semiconductor layer 150 has a convex profile. Thus, in some embodiments, the semiconductor layer 154 is formed on the edge portions of the semiconductor layer 150 in the NMOS region 302, as shown in FIG. 7F. In some embodiments, a top surface of the semiconductor layer 154 in the PMOS region 304 and a top surface of the semiconductor layer 150 in the NMOS region 302 are located at substantially the same level along the Z direction, as shown in FIG. 7F (an imaginary line is added to show the level of the top surfaces). In some embodiments, the top surface of the semiconductor layer 154 is substantially flat, as shown in FIG. 7F. In some embodiments, the top surface of the semiconductor layer 154 is curved, such as having a concave profile, as a result of the multi-cycle dep-etch process.

In some embodiments, the sidewalls of the openings between the adjacent stacks of semiconductor layers 104 in the NMOS region 302 and the PMOS region 304 are free of the semiconductor layer 154, and the semiconductor layer 154 is formed at the bottom of the opening between the adjacent stacks of semiconductor layers 104 in the PMOS region 304, while an insignificant amount of the semiconductor layer 154 is formed at the bottom of the opening between the adjacent stacks of semiconductor layers 104 in the NMOS region 302. Thus, in some embodiments, the semiconductor layer 154 is selectively formed in the PMOS region 304 in a bottom-up fashion.

Next, as shown in FIG. 7G, a dielectric layer 156 is formed on the semiconductor layer 150 and the semiconductor layer 154 in the NMOS region 302 and on the semiconductor layer 154 in the PMOS region 304. The dielectric layer 156 may be formed by first forming a dielectric layer on the exposed surfaces of the semiconductor device structure 100, followed by one or more etch processes to remove portions of the dielectric layer other than the dielectric layer 156. A sacrificial layer (not shown), such as a bottom anti-reflective coating (BARC) layer, may be used to assist with the removal of the portions of the dielectric layer formed on the sidewalls of the stacks of semiconductor layers 104. The dielectric layer 156 may include any suitable dielectric material. In some embodiments, the dielectric layer 156 includes SiN. The dielectric layer 156 may be formed by any suitable process. In some embodiments, the dielectric layer 156 is formed by CVD or PECVD.

In some embodiments, as shown in FIG. 7G, the top surface of the dielectric layer 156 in the PMOS region 304 and the top surface of the dielectric layer 156 in the NMOS region 302 are at the same level along the Z direction. In some embodiments, the thickness of the dielectric layer 156 along the Z direction ranging from about 5 nm to about 10 nm, such as about 7 nm. A combined thickness of the semiconductor layer 154 and the dielectric layer 156 in the PMOS region 304 may range from about 8 nm to about 12 nm, such as about 10 nm. In some embodiments, the top surface of the dielectric layer 156 is located at a level higher than a centerline of the dielectric spacer 416 along the Z direction, such as at a level higher than the top surface of the dielectric spacer 416. With the combination of the semiconductor layer 154 and the dielectric layer 156 formed over the recessed semiconductor layer 150 in the PMOS region 304, the risk of exposing the substrate portion 102 in the opening between the adjacent stacks of semiconductor layers 104 along the X direction is substantially reduced. As a result, source/drain region current leakage is reduced. In some embodiments, the combined thickness of the semiconductor layer 154 and the dielectric layer 156 in the PMOS region 304 is greater than the combined thickness of the semiconductor layer 154 and the dielectric layer 156 in the NMOS region 302, as shown in FIG. 7G.

As shown in FIG. 7H, the source/drain (S/D) regions 158 are formed from the first semiconductor layers 106. The S/D regions 158 may grow both vertically and horizontally to form facets, which may correspond to crystalline planes of the material used for the first semiconductor layers 106. In this disclosure, a source region and a drain region are interchangeably used, and the structures thereof are substantially the same. Furthermore, source/drain region(s) may refer to a source or a drain, individually or collectively dependent upon the context. The S/D regions 158 may be made of one or more layers of Si, SiP, SiC and SiCP for n-channel FETs or Si, SiGe, Ge for p-channel FETs. For p-channel FETs, p-type dopants, such as boron (B), may also be included in the S/D regions 146. The S/D regions 146 may be formed by an epitaxial growth method using CVD, ALD or MBE. In some embodiments, the S/D regions 158 are first formed in the PMOS region 304, while the NMOS region 302 is covered by a sacrificial layer. Then, during the formation of the S/D regions 158 in the NMOS region 302, the S/D regions 158 formed in the PMOS region 304 are covered by a sacrificial layer. As described above, with the combination of the semiconductor layer 154 and the dielectric layer 156 in the PMOS region 304, the risk of the S/D region 158 contacting the substrate portion 102 is reduced.

FIG. 8 is a perspective view of the semiconductor device structure 100 shown in FIG. 7H, in accordance with some embodiments. FIG. 8 illustrates the semiconductor device structure 100 in the PMOS region 304. As shown in FIG. 8, the semiconductor layer 150, the semiconductor layer 154, the dielectric layer 156, and the S/D regions 158 are formed over each substrate portion 102 of each fin 202. As described above, in some embodiments, the semiconductor layer 150 includes undoped crystalline silicon, the semiconductor layer 154 includes amorphous undoped silicon, and the S/D region 158 includes doped crystalline Si or SiGe.

FIGS. 9, 10, and 11 are cross-sectional side views of various stages of manufacturing the semiconductor device structure 100 taken along line B-B of FIG. 8, in accordance with some embodiments. After the formation of the S/D regions 158, subsequent processes may be performed to complete the semiconductor device structure 100. For example, a contact etch stop layer (CESL) 502 may be formed on the S/D regions 158, and an interlayer dielectric (ILD) layer 504 may be formed on the CESL, as shown in FIG. 9. The CESL 502 may include an oxygen-containing material or a nitrogen-containing material, such as silicon nitride, silicon carbon nitride, silicon oxynitride, carbon nitride, silicon oxide, silicon carbon oxide, the like, or a combination thereof. The CESL 502 may be formed by CVD, PECVD, ALD, or any suitable deposition technique. In some embodiments, the CESL 502 is a conformal layer formed by the ALD process. The materials for the ILD layer 504 may include an oxide formed by tetraethylorthosilicate (TEOS), un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 504 may be deposited by a PECVD process or other suitable deposition technique. In some embodiments, after formation of the ILD layer 504, the semiconductor device structure 100 may be subject to a thermal process to anneal the ILD layer 504.

Then, the sacrificial gate stacks 404 and the second semiconductor layers 108 are removed, and a gate dielectric layer 506 and a gate electrode layer 508 are formed to surround exposed portions of the first semiconductor layers 106, as shown in FIG. 9. The sacrificial gate electrode layer 408 may be first removed by any suitable process, such as dry etch, wet etch, or a combination thereof, followed by the removal of the sacrificial gate dielectric layer 406, which may be performed by any suitable process, such as dry etch, wet etch, or a combination thereof. In some embodiments, a wet etchant such as a tetramethylammonium hydroxide (TMAH) solution can be used to selectively remove the sacrificial gate electrode layer 408. The removal of the second semiconductor layers 108 exposes the dielectric spacers 416 and the first semiconductor layers 106. The removal of the second semiconductor layers 108 may be performed by any suitable processes, such as dry etch, wet etch, or a combination thereof. The etch process may be a selective etch process. In some embodiments, the gate dielectric layer 506 includes a high-K dielectric material, such as a dielectric material having a K value greater than 9. Examples of high-K dielectric material include HfO₂, HfSiO, HfSiON, HfTaO, HfTiO, HfZrO, zirconium oxide, aluminum oxide, titanium oxide, hafnium dioxide-alumina (HfO₂—Al₂O₃) alloy, other suitable high-K dielectric materials, and/or combinations thereof. In some embodiments, the dielectric constant of the gate dielectric layer 506 is greater than a dielectric constant of the spacer 412 or a dielectric constant of the CESL 502. The gate dielectric layers 506 may be formed by any suitable processes, such as ALD processes. The gate electrode layer 508 is formed on the gate dielectric layer 506 to surround a portion of each first semiconductor layer 106. The gate electrode layer 508 includes one or more layers of conductive material, such as polysilicon, aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, other suitable materials, and/or combinations thereof. The gate electrode layers 508 may be formed by PVD, CVD, ALD, electro-plating, or other suitable method. In some embodiments, the gate electrode layer 508, the gate dielectric layer 506, and the spacers 412 are collectively referred to as a gate structure 505.

As shown in FIG. 10, an etch stop layer 510 and another ILD layer 512 are formed over the ILD layer 504 and the gate electrode layer 508. The etch stop layer 510 may include the same material as the CESL 502, and the ILD layer 512 may include the same material as the ILD layer 504. As shown in FIG. 11, In some embodiments, a conductive feature 514 is formed in the ILD layer 512, the etch stop layer 510, the ILD layer 504, and the CESL 502, and a silicide layer 516 is formed between the conductive feature 514 and the S/D region 158. The conductive feature 514 is electrically connected to the S/D region 158. The conductive feature 514 may include any suitable electrically conductive material. In some embodiments, the conductive feature 514 may include tungsten (W), platinum (Pt), tantalum (Ta), titanium (Ti), copper (Cu), cobalt (Co), ruthenium (Ru), rhodium (Rh), iridium (Ir), molybdenum (Mo), or other suitable metal. The silicide layer 516 may include any suitable material, such as titanium silicide, cobalt silicide, nickel silicide, tungsten silicide, copper silicide, or molybdenum silicide. A conductive feature 518 is formed in the ILD layer 512 and the etch stop layer 510, and the conductive feature 518 is electrically connected to the gate electrode layer 508. The conductive feature 518 may include any suitable electrically conductive material. In some embodiments, the conductive feature 518 includes the same material as the conductive feature 514. In some embodiments, the conductive feature 518 and the conductive feature 514 include different materials. The conductive features 514, 518 may be formed at the same time or at different times.

The present disclosure in various embodiments provides a semiconductor device structure 100 including a semiconductor layer 150, a semiconductor layer 154 disposed on the semiconductor layer 150, and a dielectric layer 156 disposed on the semiconductor layer 154. Some embodiments may achieve advantages. For example, the combined thickness of the semiconductor layer 154 and the dielectric layer 156 covers the substrate portion 102, which prevents source/drain region current leakage.

An embodiment is a semiconductor device structure. The semiconductor device structure includes a first semiconductor layer disposed adjacent a substrate portion and a second semiconductor layer disposed on the first semiconductor layer. The first and second semiconductor layers are distinct from each other. The structure further includes a dielectric layer disposed on the second semiconductor layer, a source/drain region disposed on the dielectric layer, an interlayer dielectric layer disposed over the source/drain region, and a first conductive feature disposed through the interlayer dielectric layer. The first conductive feature is electrically connected to the source/drain region. The structure further includes a gate structure including a gate dielectric layer and a spacer having a first sidewall interfacing the gate dielectric layer and a second sidewall facing away from the gate structure. The structure further includes a contact etch stop layer extending along and interfacing the second sidewall of the spacer, and a dielectric constant of the gate dielectric layer is greater than a dielectric constant of the spacer or a dielectric constant of the contact etch stop layer.

Another embodiment is a semiconductor device structure. The semiconductor device structure includes a first semiconductor layer disposed in an NMOS region and a second semiconductor layer disposed in a PMOS region. A thickness of the second semiconductor layer is less than a thickness of the first semiconductor layer. The structure further includes a third semiconductor layer disposed on the second semiconductor layer in the PMOS region, a first dielectric layer disposed on the first semiconductor layer in the NMOS region, and a second dielectric layer disposed on the third semiconductor layer in the PMOS region. A top surface of the second dielectric layer is located at a same level as a top surface of the first dielectric layer. The structure further includes a first source/drain region disposed on the first dielectric layer in the NMOS region, a second source/drain region disposed on the second dielectric layer in the PMOS region, an interlayer dielectric layer disposed over the first source/drain region, and a first conductive feature disposed through the interlayer dielectric layer. The first conductive feature is electrically connected to the first source/drain region. The structure further includes a gate structure including a gate dielectric layer and a spacer having a first sidewall interfacing the gate dielectric layer and a second sidewall facing away from the gate structure. The structure further includes a contact etch stop layer extending along and interfacing the second sidewall of the spacer, and a dielectric constant of the gate dielectric layer is greater than a dielectric constant of the spacer or a dielectric constant of the contact etch stop layer.

A further embodiment is a method. The method includes forming a stack of first and second semiconductor layers, forming a sacrificial gate stack over a portion of the stack of first and second semiconductor layers, removing exposed portions of the stack of first and second semiconductor layers to expose a substrate portion, depositing a first semiconductor layer over the substrate portion, removing a portion of the first semiconductor layer in a PMOS region, forming a second semiconductor layer on the first semiconductor layer in the PMOS region, depositing a dielectric layer on the second semiconductor layer in the PMOS region and on the first semiconductor layer in an NMOS region, and forming source/drain regions over the dielectric layer in the PMOS region and the NMOS region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device structure, comprising:
a first semiconductor layer disposed adjacent a substrate portion;
a second semiconductor layer disposed on the first semiconductor layer, wherein the first and second semiconductor layers are distinct from each other;
a dielectric layer disposed on the second semiconductor layer;
a source/drain region disposed on the dielectric layer;
an interlayer dielectric layer disposed over the source/drain region;
a first conductive feature disposed through the interlayer dielectric layer, wherein the first conductive feature is electrically connected to the source/drain region;
a gate structure, comprising:
a gate dielectric layer; and
a spacer having a first sidewall interfacing the gate dielectric layer and a second sidewall facing away from the gate structure; and
a contact etch stop layer extending along and interfacing the second sidewall of the spacer, wherein a dielectric constant of the gate dielectric layer is greater than a dielectric constant of the spacer or a dielectric constant of the contact etch stop layer.

2. The semiconductor device structure of claim 1, wherein the first semiconductor layer comprises a crystalline semiconductor material, and the second semiconductor layer comprises an amorphous semiconductor material.

3. The semiconductor device structure of claim 2, wherein the first semiconductor layer comprises undoped crystalline silicon, and the second semiconductor layer comprises undoped amorphous silicon.

4. The semiconductor device structure of claim 1, further comprising one or more semiconductor layers in contact with the source/drain region.

5. The semiconductor device structure of claim 4, wherein the gate structure further comprises a gate electrode layer surrounding a portion of each of the one or more semiconductor layers.

6. The semiconductor device structure of claim 5, further comprising dielectric spacer disposed between the gate electrode layer and the dielectric layer.

7. The semiconductor device structure of claim 6, wherein a top surface of the dielectric layer is located at a level above a top surface of the dielectric spacer.

8. A semiconductor device structure, comprising:
a first semiconductor layer disposed in an NMOS region;
a second semiconductor layer disposed in a PMOS region, wherein a thickness of the second semiconductor layer is less than a thickness of the first semiconductor layer;
a third semiconductor layer disposed on the second semiconductor layer in the PMOS region;
a first dielectric layer disposed on the first semiconductor layer in the NMOS region;
a second dielectric layer disposed on the third semiconductor layer in the PMOS region, wherein a top surface of the second dielectric layer is located at a same level as a top surface of the first dielectric layer;
a first source/drain region disposed on the first dielectric layer in the NMOS region;
a second source/drain region disposed on the second dielectric layer in the PMOS region;
an interlayer dielectric layer disposed over the first source/drain region;
a first conductive feature disposed through the interlayer dielectric layer, wherein the first conductive feature is electrically connected to the first source/drain region;
a gate structure, comprising:
a gate dielectric layer; and
a spacer having a first sidewall interfacing the gate dielectric layer and a second sidewall facing away from the gate structure; and
a contact etch stop layer extending along and interfacing the second sidewall of the spacer, wherein a dielectric constant of the gate dielectric layer is greater than a dielectric constant of the spacer or a dielectric constant of the contact etch stop layer.

9. The semiconductor device structure of claim 8, further comprising a fourth semiconductor layer disposed between the first semiconductor layer and the first dielectric layer in the NMOS region.

10. The semiconductor device structure of claim 9, wherein a top surface of the first semiconductor layer has a convex profile, and the fourth semiconductor layer is disposed on edge portions of the top surface of the first semiconductor layer.

11. The semiconductor device structure of claim 8, wherein a top surface of the third semiconductor layer is flat.

12. The semiconductor device structure of claim 8, wherein a top surface of the third semiconductor layer is located at a same level as a top surface of the first semiconductor layer.

13. The semiconductor device structure of claim 8, wherein the first and second semiconductor layers each comprises a crystalline semiconductor material, and the third semiconductor layer comprises an amorphous semiconductor material.

14. The semiconductor device structure of claim 13, wherein the first and second semiconductor layers each comprises undoped crystalline silicon, and the third semiconductor layer comprises undoped amorphous silicon.

15. A method, comprising:
forming a stack of first and second semiconductor layers;
forming a sacrificial gate stack over a portion of the stack of first and second semiconductor layers;
removing exposed portions of the stack of first and second semiconductor layers to expose a substrate portion;
depositing a first semiconductor layer over the substrate portion;
removing a portion of the first semiconductor layer in a PMOS region;
forming a second semiconductor layer on the first semiconductor layer in the PMOS region;
depositing a dielectric layer on the second semiconductor layer in the PMOS region and on the first semiconductor layer in an NMOS region; and
forming source/drain regions over the dielectric layer in the PMOS region and the NMOS region.

16. The method of claim 15, wherein the second semiconductor layer is deposited on the first semiconductor layer in the NMOS region.

17. The method of claim 16, wherein a deposition rate of the second semiconductor layer in the PMOS region is faster than a deposition rate of the second semiconductor layer in the NMOS region.

18. The method of claim 17, wherein the second semiconductor layer is formed in the PMOS region and the NMOS region by a multi-cycle dep-etch process.

19. The method of claim 18, wherein the multi-cycle dep-etch process comprises a plasma enhanced chemical vapor deposition process and a plasma etch process.

20. The method of claim 19, wherein a plasma frequency of the plasma enhanced chemical vapor deposition process is less than a plasma frequency of the plasma etch process.
